(19) United States
(12) Patent Application Publication
(10) Pub. No.: US 2025/0290224 A1
(43) Pub. Date: Sep. 18, 2025

(54) HIGH DEFECT SiC WAFER WITH DEVICE LAYER AND METHODS OF MANUFACTURE

(71) Applicant: Microchip Technology Incorporated, Chandler, AZ (US)

(72) Inventors: Steve Nagel, Chandler, AZ (US); Bomy Chen, Newark, CA (US)

(73) Assignee: Microchip Technology Incorporated, Chandler, AZ (US)

(21) Appl. No.: 18/747,545

(22) Filed: Jun. 19, 2024

Related U.S. Application Data
(60) Provisional application No. 63/566,847, filed on Mar. 18, 2024.

(51) Int. Cl. C30B 23/02; B28D 5/04; C30B 25/18; C30B 29/36; H01L 29/16; H01L 29/66; H01L 29/78

(52) U.S. Cl. CPC C30B 23/02; C30B 25/183; C30B 29/36; H10D 12/031; H10D 30/66; H10D 62/8325; B28D 5/045

(57) ABSTRACT

Aspects provide forming hLDD SiC substrate wafers having a number of defects per square centimeter in excess of a predetermined threshold, and using the hLDD SiC substrate wafers to make vertical diffused metal oxide semiconductor (DMOS) field effect transistors (FET). In particular, methods comprise: growing by deposition a SiC ingot; slicing the SiC ingot to produce a plurality of base drift wafers; identifying base drift wafers having a number of defects per square centimeter in excess of a predetermined threshold; and forming a respective device layer on the identified base drift wafers. An aspect provides a DMOS FET having a base drift layer on the device layer and comprising SiC and having a number of defects per square centimeter in excess of a predetermined threshold.

### PRIORITY STATEMENT

The application claims priority to U.S. Provisional Patent Application No. 63/566,847, filed Mar. 18, 2024, the contents of which are hereby incorporated in their entirety.

### TECHNICAL FIELD

The present disclosure relates to silicon carbide (SiC) wafers, in particular to processes to create usable SiC substrate wafers and SiC substrate/device layer hybrid wafers.

### BACKGROUND

Silicon carbide (SiC) wafers are created according to a typical process. A cylindrical SiC ingot, called a boule, is grown from a SiC seed. High-purity silicon powder and high-purity carbon powder are used to grow SiC single crystals by physical vapor transport (PVT) to form the boule. SiC substrate wafers are made by slicing the ingot (boule) with a multi-wire wafer saw to cut the SiC crystal into thin slices with thickness of no more than 1 mm. The surfaces of the SiC substrate wafers are then processed by mechanical grinding and polishing using diamond slurry of different particle sizes to grind the wafers to the desired flatness and roughness. Finally, the surfaces of the SiC substrate wafers are polished to a mirror finish by chemical mechanical polishing (CMP) to complete the SiC substrate wafers.

Defect density (DD) is a vital metric in semiconductor manufacturing. Any inconsistencies, impurities, or flaws in the manufacturing process can lead to the malfunctioning of a semiconductor device, also known as a chip, or even an entire batch. Defect density (DD) is an industry metric that refers to the number of defects present per unit area on a wafer, usually expressed in terms of defects per square centimeter (def/cm²). Defects may include: crystallographic defects within the wafer, and surface defects at or near the wafer surface. Crystallographic defects may include Basal plane dislocations (BPDs), threading screw dislocations (TSCs), micropipes, and grain boundaries, without limitation. Surface defects may include carrot defects, polytype inclusions, and scratches, without limitation. DD less than 1000 def/cm² is generally acceptable. DD between 1000 def/cm² and 100,000 def/cm² may be acceptable, depending upon the device and defect type. DD greater than 100,000 def/cm² is generally not acceptable.

The cost of SiC substrate wafers is very high and there is a lot of yield loss due to crystalline defects. In particular, the ingot will have inherent defects, such as crystal lattice defects caused by strains that develop when the SiC ingot is grown from a SiC seed. SiC wafers having high Lattice Defect Density (hLDD) are either be downgraded as unusable material or remelted and recycled to grow a new SiC ingot. A problem with a typical SiC wafer creation process is that faster processing results in a greater number of hLDD SiC substrate wafers produced. To reduce the number of hLDD SiC substrate wafers produced, the entire process is allowed to progress slowly, which is a further cost driver of the typical process.

There is a need for an improved process to quickly create usable hLDD SiC substrate wafers and hLDD SiC substrate/device layer hybrid wafers.

### SUMMARY OF THE INVENTION

According to an aspect, there is provided a method comprising forming hLDD SiC substrate wafers having a number of defects per square centimeter in excess of a predetermined threshold, and using the hLDD SiC substrate wafers to make vertical diffused metal oxide semiconductor (DMOS) field effect transistors (FET).

According to an aspect, there is provided a method comprising: growing by deposition a silicon carbide (SiC) ingot; slicing the SiC ingot to produce a plurality of base drift wafer; identifying ones of the plurality of base drift wafers having a number of defects per square centimeter in excess of a predetermined threshold; and forming a respective device layer on the identified ones of the plurality of base drift wafer.

An aspect as in the previous paragraph provides, a method wherein the device layer comprises silicon, gallium nitride, or silicon carbide.

An aspect as in one of the previous two paragraphs provides, a method comprising: forming first and second doped regions within a base drift wafer and spaced apart with a current flow region between the first and second doped regions; forming first and second source regions within the first and second doped regions, respectively; and forming a gate insulated from a base drift wafer by an insulation layer, positioned above the current flow region between the first and second doped regions, and positioned at least partly above the first and second doped regions.

An aspect as in one of the previous three paragraphs provides, a method comprising: forming a drain contact on a device layer.

An aspect as in one of the previous four paragraphs provides, a method wherein forming a device layer comprises bonding the device layer to a base drift wafer.

An aspect as in one of the previous five paragraphs provides, a method wherein forming the device layer comprises: growing a device layer by deposition on a substrate; positioning the device layer in contact with the base drift wafer; bonding the device layer to the base drift wafer; and removing the substrate from the device layer.

An aspect as in one of the previous six paragraphs provides, a method comprising annealing a device layer on the base drift wafer.

An aspect as in one of the previous seven paragraphs provides, a method comprising forming a buffer layer between a base drift wafer and a device layer.

An aspect as in one of the previous eight paragraphs provides, a method wherein the buffer layer comprises a polycrystalline or amorphous SiC layer, and wherein forming the buffer layer comprises chemical vapor deposition or atomic layer deposition.

According to an aspect, there is provided a device comprising: a drain contact; a device layer on the drain contact; a base drift layer on the device layer, the drift layer comprising silicon carbide (SiC) and having a number of defects per square centimeter in excess of a predetermined threshold; first and second doped regions within the base drift layer and spaced apart from with a current flow region between the first and second doped regions; first and second source regions within the first and second doped regions, respectively; and a gate insulated from the base drift layer by an insulation layer, positioned above the current flow region between the first and second doped regions, and positioned at least partly above the first and second doped regions.

An aspect as in the previous paragraph provides, a device wherein a device layer comprises silicon.

An aspect as in one of the previous two paragraphs provides, a device wherein a device layer comprises gallium nitride.

An aspect as in one of the previous three paragraphs provides, a device wherein a device layer comprises silicon carbide.

An aspect as in one of the previous four paragraphs provides, a device wherein a device layer is bonded to the base drift layer.

An aspect as in one of the previous five paragraphs provides, a device wherein a device layer and the base drift layer are annealed.

An aspect as in one of the previous six paragraphs provides, a device comprising a buffer layer between the base drift layer and a device layer.

An aspect as in one of the previous seven paragraphs provides, a device wherein the buffer layer comprises a polycrystalline or amorphous SiC film.

According to an aspect, there is provided a device comprising: a drain contact; a device layer on the drain contact and comprising gallium nitride; a base drift layer on the device layer, the base drift layer comprising silicon carbide (SiC) and having in excess of 1,000 defects per square centimeter; first and second doped regions within the base drift layer and spaced apart with a current flow region between the first and second doped regions; first and second source regions within the first and second doped regions, respectively; and a gate insulated from the base drift layer by an insulation layer, positioned above the current flow region between the first and second doped regions, and positioned at least partly above the first and second doped regions.

An aspect as in the previous paragraph provides, a device comprising a buffer layer between a device layer and a base drift layer, wherein the buffer layer comprises a polycrystalline or amorphous SiC layer.

An aspect as in one of the previous two paragraphs provides, a device wherein a device layer is bonded to a base drift layer.

### BRIEF DESCRIPTION OF THE DRAWINGS

The figures illustrate examples of hLDD SiC substrate wafers and hLDD SiC substrate/device layer hybrid wafers, hLDD SiC DMOS FETs, and methods for creating hLDD SiC substrate wafers and hLDD SiC substrate/device layer hybrid wafers, and for using the wafers to make hLDD SiC DMOS FETs.

FIG. 1A shows a SiC seed wafer to be used as a base upon which to grow an ingot.

FIG. 1B shows an SiC ingot epitaxially grown from the SiC seed, wherein the SiC ingot has high Lattice Defect Density.

FIG. 1C shows the hLDD SiC ingot being sliced to make hLDD SiC wafers.

FIG. 1D shows the hLDD SiC wafers being mechanically ground and polished.

FIG. 1E shows the hLDD SiC wafers undergoing chemical mechanical polish (CMP) to produce a mirror surface finish.

FIG. 2 shows a cross-sectional, side view of a hLDD SiC substrate with a device layer hybrid wafer comprising a base drift layer and a device layer.

FIG. 3 shows a cross-sectional, side view of a hLDD SiC substrate/device layer hybrid wafer comprising a base drift layer, a buffer layer, and a device layer.

FIG. 4 shows a cross-sectional, perspective view of a vertical DMOS FET made using a hLDD SiC substrate/device layer hybrid wafer.

FIG. 5 shows a method for making a hLDD SiC substrate with a device layer hybrid wafer.

The reference number for any illustrated element that appears in multiple different figures has the same meaning across the multiple figures, and the mention or discussion herein of any illustrated element in the context of any particular figure also applies to each other figure, if any, in which that same illustrated element is shown.

DESCRIPTION

Normally rejected hLDD SiC substrate wafers may have a device layer applied thereto so that the hLDD SiC substrate wafers may be used as a hybrid substrate. The hLDD SiC substrate wafers that are normally rejected for device fabrication may be used as a base drift layer of a hybrid wafer having a device layer on top of the drift layer. The lattice defects of the hLDD SiC substrate wafer may act as a stress relief to buffer the stress caused by lattice mismatches of dissimilar materials when bonding a low defect semiconductor on top of the hLDD SiC substrate wafer. A top device layer may be bonded to the hLDD SiC substrate wafer, which top device layer may be a material such as silicon or gallium nitride (GaN). Optionally, a polycrystalline or amorphous SiC film can be deposited on the hLDD SiC substrate wafer, prior to application of the device layer, to further buffer stress.

The resulting hybrid wafer may allow for the device switching to occur in the top, low defect semiconductor material while also benefitting from having SiC in the drift region to handle high voltages as well as improved thermal conductivity.

This solution takes advantage of the high lattice defects in the hLDD SiC substrate wafer to buffer stress between two dissimilar materials. An optional buffer layer of polycrystalline or amorphous SiC can also be deposited on top of the hLDD SiC substrate wafer to further buffer stress. Additionally, the boule creation process may be sped up significantly, reducing cost and creating more hLDD SiC substrate wafers.

Hybrid wafers having an hLDD SiC substrate wafer may be created according to a process that is relatively faster than a process to create normal SiC wafers. High-purity silicon powder and high-purity carbon powder may be used to grow SiC single crystals by physical vapor transport (PVT) until a SiC ingot is grown from a SiC seed. The SiC ingot may be grown relatively faster than a normal process because high Lattice Defect Density (hLDD) SiC is expected and tolerated. The hLDD SiC ingot is then sliced into wafers with a multi-wire dicing machine, which cuts the hLDD SiC ingot into hLDD SiC substrate wafers less than 1 mm thick. In some cases, the wafers may be 0.1 mm thick. The surfaces of the hLDD SiC substrate wafers are then processed by mechanical grinding and polishing using diamond slurry of different particle sizes to grind the hLDD SiC substrate wafers to the desired flatness and roughness. A device layer is created on the hLDD SiC substrate wafers to create hybrid wafers. The device layer may comprise a semiconductor material, such as silicon or gallium nitride (GaN) without limitation, and may have a thickness between 1 and 10 μm. The device layer may be grown on the hLDD SiC substrate wafer by deposition to create a hybrid wafer. In an alternative example, a buffer layer may be applied between the hLDD SiC substrate wafer and the device layer to reduce lattice mismatch with the substrate, wherein the buffer layer may be a polycrystalline or amorphous SiC film grown by chemical vapor deposition (CVD), such as atomic layer deposition (ALD), without limitation. Finally, the surfaces of the hybrid wafers are polished to a mirror finish by chemical mechanical polishing (CMP) to complete the hybrid wafers. The hybrid wafers may be analyzed after polishing by optical microscopes and other instruments to detect the Lattice Defect Density, micropipe density, surface roughness, resistivity, warp, total thickness variation (TTV), surface scratches, and other parameters of the hybrid wafers, for quality control purposes.

A gallium nitride (GaN) substrate may be bonded to a hLDD SiC wafer. The hLDD SiC wafer may first be cleaned of contaminate particles and organic matter on the surfaces of GaN substrate and SiC wafer by washing with alcohol and acetone, and then immersing in RCA solution (NH₄OH: H₂O₂: H₂O=1:1:5) and 1% HF solution respectively to remove any natural oxide. The RCA solution may be as provided by Radio Corporation of America as part of an RCA cleaning process. Then, the GaN substrates and SiC wafers may be placed in an oven (90° C.) to dry, e.g., for 30 minutes. The dry substrate and wafer surfaces may then be activated by Ar plasma (2 keV) in a reactive ion etching (RIE) chamber with an Ar ion bombardment dose, e.g., of 1×10¹⁵ cm⁻² for 60 seconds. After activation, the GaN substrate and SiC wafer may be placed in a bonding chamber, e.g., at 1×10⁻⁵ mbar vacuum for 5 minutes with an applied bonding force of 10 kN to ensure full contact between the GaN substrate and the SiC wafer to form a hybrid wafer. The hybrid wafers may then be annealed, e.g., at 200° C. to relieve amorphous SiC and amorphous GaN at the boundary.

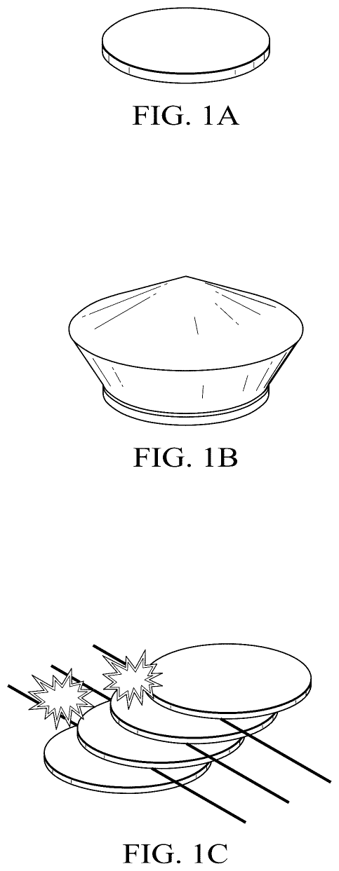

FIGS. 1A-1E show a process for making hLDD SiC wafers to be used as base drift layers in hybrid wafers. FIG. 1A shows a SiC seed wafer to be used as a base upon which to grow an ingot. FIG. 1B shows a SiC ingot epitaxially grown by deposition from the SiC seed wafer of FIG. 1A. The SiC ingot may have inherent defects, such as strains. FIG. 1C shows the SiC ingot of FIG. 1B being sliced to make base drift wafers. The base drift wafers may have inherent scratches and other defects from being sliced. The base drift wafers may have a number of defects per square centimeter in excess of a predetermined threshold. FIG. 1D shows the base drift wafers of FIG. 1C being mechanically ground and polished. FIG. 1E shows the base drift wafers of FIG. 1D undergoing chemical mechanical polish (CMP) to produce a mirror surface finish. While grinding, polishing, and chemical/mechanical polishing may remove some surface defects, the base drift wafers may have a high Lattice Defect Density (hLDD). These hLDD base drift wafers may be used as base drift layers in hybrid wafers.

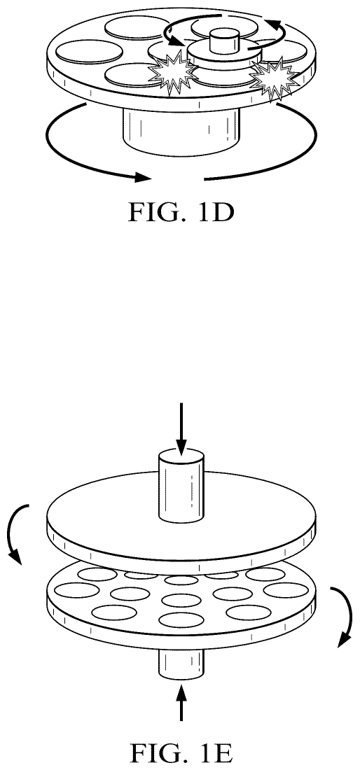

FIG. 2 shows a cross-sectional, side view of a hybrid wafer 200 comprising a base drift layer 270 and a device layer 280. The base drift layer 270 may be from a base drift wafer. The device layer 280 may comprise silicon, gallium nitride, without limitation.

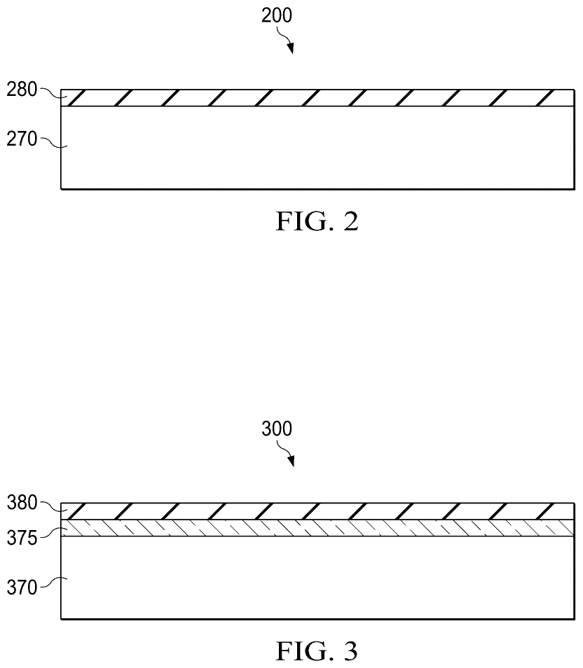

FIG. 3 shows a cross-sectional, side view of a hybrid wafer 300 comprising a base drift layer 370, a buffer layer 375, and a device layer 380. The base drift layer 370 may be from a base drift wafer. The device layer 380 may comprise silicon, gallium nitride, without limitation. The buffer layer 375 may comprise a polycrystalline or amorphous SiC layer.

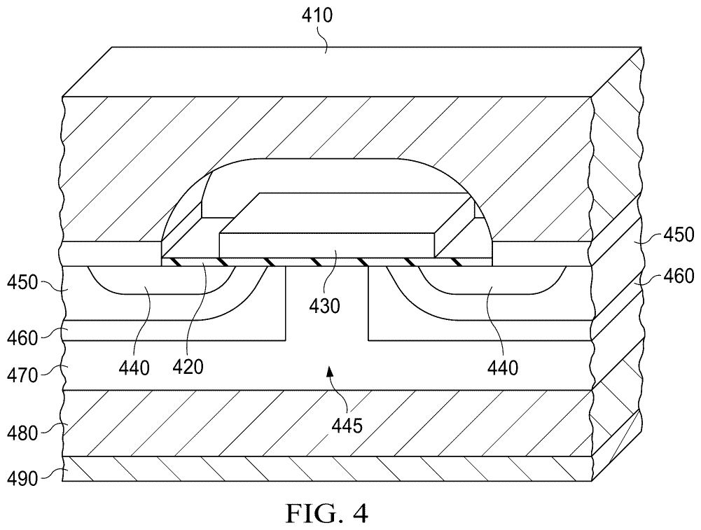

FIG. 4 shows a cross-sectional, perspective view of a vertical diffused metal oxide semiconductor (DMOS) field effect transistor (FET) made using a hybrid wafer, wherein the hybrid wafer comprises a hLDD base drift wafer, with a device layer above the hLDD base drift wafer. The hLDD base drift layer of a hybrid wafer as described in FIGS. 2 and 3 may be used as a N⁺device layer 480 and a drift layer 470 of the transistor shown in FIG. 4. The base drift layer 470 may be a N⁻epitaxial base drift layer. As shown in FIG. 4, from the top into the base drift layer 470 there are formed N⁺doped first and second source regions 440 surrounded by first and second P-doped regions 450, which form the P-base that can be surrounded by respective out diffusion areas 460. A source contact metal layer 410 may generally contact both source regions 440 and P-doped regions 450 on the surface of the die and also connects both left and right source regions. An insulating layer 420, typically oxide, silicon dioxide, or any other suitable material, insulates a polysilicon gate 430, which covers or is positioned above at least a part of the P-base regions 450 and out diffusion areas 460. The gate 430 is connected to a gate contact (not shown) which is usually formed by another metal layer. The gate 430 may be insulated from the base drift layer 470 by an insulation layer 420. The base drift layer 470 and device layer 480 of the hybrid wafer described above are the foundation structure of the FET. The bottom side of this vertical transistor has a thin metal layer applied to the device layer 480 form the drain contact 490. FIG. 4 shows a typical elementary cell of a MOSFET that may comprise a common drain, a common gate and two source regions and two channels. Other similar cells may be used in a vertical power MOSFET. A plurality of such cells may generally be connected in parallel to form a power MOSFET in a single die.

In the ON-state, a channel is formed within the area of P-doped regions 450 covered by the gate 430 reaching from the surface into the out diffusion areas 460, respectively. Thus, current can flow from the out diffusion areas 460 and into a current flow region 445 between the out diffusion areas 460. The cell structure provides for a sufficient width of gate 430 to allow for this current to turn into a vertical current flowing through the current flow region 445 to the drain side through the base drift layer 470.

A major influence for the on resistance may be contributed by the N⁺device layer 480. By grinding the thickness of this layer down, the resistance can be substantially reduced.

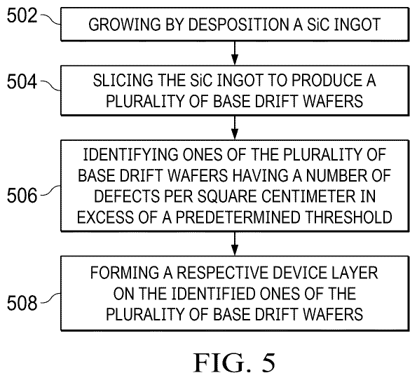

FIG. 5 shows a method for making a hybrid wafer. A SiC ingot is grown 502 by epitaxial growth or deposition. The SiC ingot is sliced 504 to produce a plurality of base drift layers. Ones of the plurality of base drift layers are identified 506 by having a number of defects per square centimeter in excess of a predetermined threshold. A respective device layer is formed 508 on the identified ones of the plurality of base drift layers.

The device layer may be formed by growing the device layer by deposition on a substrate, positioning the device layer in contact with the base drift wafer, bonding the device layer to the base drift wafer, and removing the substrate from the device layer.

Although examples have been described above, other variations and examples may be made from this disclosure without departing from the spirit and scope of these disclosed examples.

1. A method comprising:
growing by deposition a silicon carbide (SiC) ingot;
slicing the SiC ingot to produce a plurality of base drift wafer;
identifying ones of the plurality of base drift wafers having a number of defects per square centimeter in excess of a predetermined threshold; and
forming a respective device layer on the identified ones of the plurality of base drift wafer.

2. The method of claim 1, wherein the device layer comprises silicon, gallium nitride, or silicon carbide.

3. The method of claim 1, comprising:
forming first and second doped regions within a base drift wafer and spaced apart with a current flow region between the first and second doped regions;
forming first and second source regions within the first and second doped regions, respectively; and
forming a gate insulated from a base drift wafer by an insulation layer, positioned above the current flow region between the first and second doped regions, and positioned at least partly above the first and second doped regions.

4. The method of claim 1, comprising: forming a drain contact on a device layer.

5. The method of claim 1, wherein forming a device layer comprises bonding the device layer to a base drift wafer.

6. The method of claim 1, wherein forming the device layer comprises:
growing a device layer by deposition on a substrate;
positioning the device layer in contact with the base drift wafer;
bonding the device layer to the base drift wafer; and
removing the substrate from the device layer.

7. The method of claim 1, comprising annealing a device layer on the base drift wafer.

8. The method of claim 1, comprising forming a buffer layer between a base drift wafer and a device layer.

9. The method of claim 8, wherein the buffer layer comprises a polycrystalline or amorphous SiC layer, and wherein forming the buffer layer comprises chemical vapor deposition or atomic layer deposition.

10. A device comprising:
a drain contact;
a device layer on the drain contact;
a base drift layer on the device layer, the drift layer comprising silicon carbide (SiC) and having a number of defects per square centimeter in excess of a predetermined threshold;
first and second doped regions within the base drift layer and spaced apart from with a current flow region between the first and second doped regions;
first and second source regions within the first and second doped regions, respectively;
and
a gate insulated from the base drift layer by an insulation layer, positioned above the current flow region between the first and second doped regions, and positioned at least partly above the first and second doped regions.

11. The device of claim 10, wherein a device layer comprises silicon.

12. The device of claim 10, wherein a device layer comprises gallium nitride.

13. The device of claim 10, wherein a device layer comprises silicon carbide.

14. The device of claim 10, wherein a device layer is bonded to the base drift layer.

15. The device of claim 14, wherein a device layer and the base drift layer are annealed.

16. The device of claim 10, comprising a buffer layer between the base drift layer and a device layer.

17. The device of claim 16, wherein the buffer layer comprises a polycrystalline or amorphous SiC film.

18. A device comprising:
a drain contact;
a device layer on the drain contact and comprising gallium nitride;
a base drift layer on the device layer, the base drift layer comprising silicon carbide (SIC) and having in excess of 1,000 defects per square centimeter;
first and second doped regions within the base drift layer and spaced apart with a current flow region between the first and second doped regions;
first and second source regions within the first and second doped regions, respectively;
and
a gate insulated from the base drift layer by an insulation layer, positioned above the current flow region between the first and second doped regions, and positioned at least partly above the first and second doped regions.

19. The device of claim 18, comprising a buffer layer between a device layer and a base drift layer, wherein the buffer layer comprises a polycrystalline or amorphous SiC layer.

20. The device of claim 18, wherein a device layer is bonded to a base drift layer.
